(19) United States
(12) Patent Application Publication
(10) Pub. No.: US 2025/0233328 A1
(43) Pub. Date: Jul. 17, 2025

(54) COVER FOR SPRING-LOADED CLAMP

(71) Applicant: C. & E. Fein GmbH, Schwaebisch Gmuend/ Bargau (DE)

(72) Inventors: Wolfgang DUERNEGGER, Schorndorf (DE); Stefan SCHERRENBACHER, Waldstetten (DE); Robert WITTLICH, Durlangen (DE)

(73) Assignee: C. & E. Fein GmbH, Schwaebisch Gmuend/ Bargau (DE)

(21) Appl. No.: 19/030,215

(22) Filed: Jan. 17, 2025

(30) Foreign Application Priority Data
Jan. 17, 2024 (EP) 24152356.2

(51) Int. Cl. H01R 4/48; H01R 12/51; H01R 12/57

(52) U.S. Cl. CPC H01R 4/4842; H01R 4/4821; H01R 12/515; H01R 12/57

(57) ABSTRACT

A cover element for covering a spring-loaded clamping device which can be connected to a printed circuit board. A connecting section connects the cover element with a connecting section of the spring-loaded clamping device and a cover portion covers a conductor mount of the spring-loaded clamping device. The cover portion has an opening channel for form-fitting and/or force-fit mounting of a connecting strand, through which a conductor of the connecting strand can be guided and inserted into the conductor mount of the spring-loaded clamping device. A clamping system and a method for manufacturing the cover element are also provided.

This nonprovisional application claims priority under 35 U.S.C. § 119(a) to European Patent Application No. 24152356.2, which was filed on Jan. 17, 2024, and which is herein incorporated by reference.

### BACKGROUND OF THE INVENTION

### Field of the Invention

The present invention relates to a cover element for a spring-loaded clamping device which is connected or can be connected to a printed circuit board, a method for manufacturing the cover element, as well as a clamping system equipped with this cover element and a power tool.

### Description of the Background Art

Power tools, in particular hand-held power tools, are used in many industries under a wide variety of operating conditions. In addition to high power density and an ergonomic device design, robustness and reliability are among the most important device requirements.

Particularly when used with metallic materials, there are many additional requirements, as the dusts emitted by the metal application can contain abrasive, electrically conductive, hot, and harmful components.

Hand-held power tools are often operated in this environment, in particular, the electrical components located inside the hand-held power tool are exposed to those emissions, since ambient air is used to cool them.

For example, as a result of the ambient air contaminated with metal particles, which is drawn through the machine housing to cool the hand-held power tool, metal particles accumulate, which can build up electrically conductive paths through progressive agglomeration. As a result of heating and short circuits, these can lead to the burning of the tools. In the worst case, this can expose the operator to danger.

As a rule, handheld power tools, especially angle grinders, are used on construction sites for as long as they are functional. Recommended maintenance and cleaning intervals are not carried out or are carried out improperly, which means that the hazards described above cannot be prevented.

Spring-loaded clamps are used to connect electronic assemblies with flexible conductors in a detachable manner. In particular, they often serve as a detachable connection between the power supply (mains cable, battery) and the electronics module. Due to topography, it is not always possible to place the mains terminals far apart from each other and thus separate the different mains potentials sufficiently far from each other. The emissions described above can lead to metal dust-induced electrically conductive paths, leakage currents and short circuits, thereby causing the successive destruction of the electronic module.

It is generally known to provide spring-loaded clamps with the conductors already connected to them by means of a material-locking coating and thus to protect the contact points (spring-loaded clamp, conductor). This coating provides sufficient protection but restricts the actual function of a spring-loaded clamp. In electrical engineering, a spring-loaded clamp is used for the detachable connection or connection of wires, conductors, and cables, and is used when a secure but detachable contact point is required, for example between a printed circuit board and a conductor. If a contact point is provided with a material-locking coating, this must be removed in the event of decontacting. This is often not possible without leaving residue. When the electronic unit with the spring-loaded clamp is reused, it is necessary to replace the material-locking coating.

There are no spring-loaded clamps available on the market that provide the necessary compactness for such electronic units or that can be assembled on printed circuit boards in a dust-proof and potting-resistant manner. Rather, the contact and actuation area of commercially available spring-loaded clamps is openly designed and thus offers no protective or barrier effect against metallic dusts.

### SUMMARY OF THE INVENTION

It is therefore an object of the invention to protect and seal a spring-loaded clamping device from environmental influences without significantly restricting its functionality, i.e., the safe but detachable contacting of conductors.

Due to the design of the cover element according to the invention, a connection configuration can be easily produced for a system containing the cover element, the spring-loaded clamping device and the connecting strand, in which the conductor of the connecting strand is clamped in the conductor mount of the spring-loaded clamping device, the connecting strand is included in the opening channel of the cover element in a form-fitting manner, and the cover element is connected to the spring-loaded clamping device and covers it. The cover portion and the form-fitting mount of the connecting strand in the opening channel prevent metal dust from entering the conductor mount.

The opening channel forms a passage through the cover portion. The opening channel is preferably hollow cylindrical and designed to accommodate a cylindrical connecting strand in a form-fitting and/or force-fit manner.

The opening channel may extend away from the cover portion, in particular the opening channel is arranged perpendicular to a planar cover portion.

The opening channel may also fulfill the task of achieving a sealing effect by means of the form-fitting and/or force-fit strand mount. On the other hand, the connecting strand is aligned by the opening channel in the direction of the conductor mount, so that the insertion of the conductor into the conductor mount is supported. In addition, the connection of the spring-loaded clamping device with the cover element and the form-fitting mount of the connecting strand in the opening channel results in dampening any vibrations acting on the connecting strand and relieving the clamping connection of the conductor with the spring-loaded clamping device. This improves the reliability of the electrical contact.

The opening channel can have at least one seal, in particular to prevent the entry of particles through the opening channel.

The seal can include a circumferential, in particular ring-shaped, protrusion section cylindrical formed in the cylindrical opening channel. In particular, the protrusion section is concentric to the circular channel cross-section on the inner wall of the opening channel. This protrusion section is designed in particular to create a force-fit connection between the opening channel and the connecting strand by pressing the protrusion section into a flexible material of an insulating jacket of the connecting strand when it is passed through the protrusion section and is received in the opening channel, and/or by the protrusion section itself being flexible or elastic. If the indented insulating jacket or the protrusion section exerts a restoring force, the connecting strand is received in the opening channel in a force-fit manner.

The seal can include a ring-shaped sealing element arranged in the cylindrical opening channel. The sealing element can be an integral part of the seal or the opening channel or, alternatively, for example, an O-ring. This sealing element is designed in particular to create a force-fit connection between the opening channel and the connecting strand by pressing the sealing element into a flexible material of an insulating jacket of the connecting strand when it is passed through the sealing element and accommodated in the opening channel, and/or by the sealing element itself being flexible or elastic.

The opening channel can extend away from the cover portion. For example, the opening channel can extend along a longitudinal axis. The opening channel can have a first opening, which ends in the interior of an opening of the cover element. The opening channel can have a channel section which has a decreasing opening cross-section in the direction of the first opening, and which ends in particular in the first opening. The opening cross-section in the first opening and/or along the entire opening channel can have a diameter of 1 mm to 4 mm and is suitable for connecting strands with different outer diameters to be inserted and passed through. These outer diameters range from 1 mm to 4 mm, preferably 2 mm to 3.7 mm and particularly preferably between 2.5 mm to 3.5 mm (including these values). This enables a dust-tight closure of inserted connection strands with different outer diameters.

The opening cross-section of the opening channel can be designed to increase from the first opening towards the second opening. In this case, the second opening is the point where a conductor is inserted into the opening channel.

In particular, the opening channel is an integral part of the cover element. However, it can also be formed as an interchangeable part. Interchangeable inserts may be provided, which can be received in a corresponding mount of the cover element, and which have different opening channels with different opening diameters, in particular to make the cover element usable for connecting strands with a greater variety of diameters. The opening channel or the interchangeable insert may have or be made of a flexible material.

The cover portion can be planar in its entirety or in sections, but it can also be curved in its entirety or in sections. In particular, the cover portion is an integral part of the cover element.

The connecting section of the cover element may be set up, in particular, for the purpose of establishing a form-fitting and/or force-fit connection with the connecting section of the spring-loaded clamping device. The connecting section of the cover element is preferably designed as a projection of the cover element, in particular as a pin or locking cam, or as a recess or opening in the cover element, each of which may be designed to engage or receive a complementary connecting section on the spring-loaded clamping device. A partial section of the cover element pointing into the interior of the cover element, in particular the opening channel, is preferably designed as a connecting section of the cover element, which engages in a form-fitting and/or force-fit manner in the conductor mount of the spring-loaded clamping device in the mounting position.

The cover element can have one, two, three or more connecting sections. These are preferably designed to engage or receive a complementary connecting section on the spring-loaded clamping device.

The cover element can be manufactured integral in design, in particular by an injection molding process or by an additive manufacturing process.

The cover element can be made of or contains an electrically non-conductive material. The material of the cover element can be in particular a plastic, in particular selected from thermosets, thermoplastics or elastomers, in particular silicones, in particular PTFE, or a combination of the aforementioned materials.

A spring-loaded clamp for electrical conductors can be used in electrical engineering to connect electrical conductors such as wires or cables safely and reliably in a reversible manner. These terminals use the force of a spring to hold the electrical conductor in place and contact it electrically without the need for soldering or screwing.

In particular, spring-loaded clamps contain a housing in which one or more metal clamping jaws can be located. When the electrical conductor is inserted, a spring of the spring-loaded clamp presses the clamping jaws together, which establishes an electrical and mechanical connection. This type of terminal is often used in electrical panels, electrical circuits, or junction boxes because it allows for a quick and safe connection and also allows for easy maintenance or removal of the conductor.

The spring-loaded clamping device can have a connecting section to connect the cover element with the spring-loaded clamping device, and a conductor mount. In particular, the spring-loaded clamping device may have one, two, three or more such connecting sections.

The clamping functionality for clamping a conductor of the connecting strand is made possible in particular by a clamping device of the spring-loaded clamping device. Optionally, the spring-loaded clamping device has a base body on which the connecting section, the conductor mount and, in particular, the clamping device are arranged. The base body can be a housing of the spring-loaded clamping device or have one.

The base body can be made of or has an electrically non-conductive material. The material of the base body can be in particular a plastic, in particular selected from thermosets, thermoplastics or elastomers, in particular silicones, especially PTFE, or a combination of the mentioned materials.

For example, the clamping device can include one or more metal clamping jaws. When the electrical conductor is inserted, a spring of the spring-loaded clamp compresses the clamping jaws, creating an electrical and mechanical connection. However, the clamping functionality can also be implemented via other clamping parts.

The conductor mount can contain an outwardly open area of the spring-loaded clamping device, through which a conductor of the connecting strand is inserted into the spring-loaded clamping device and in particular can be guided into the clamping device. If the cover element is connected to the spring-loaded clamping device in a mounting position, the opening channel of the cover element is aligned with the open area of the spring-loaded clamping device in such a way that a connecting strand inserted into the opening channel is guided through the open area. In particular, in this mounting position, a conductor of the connecting strand is inserted into the clamping device, which is aligned according to the direction of the opening channel and the open area. The orientation of the opening channel, the open area and the clamping device is in particular such that the said components are arranged along a central axis of the opening channel.

The open area can be an opening in an optional housing of the spring-loaded clamping device, or it can be realized by a missing cover of the clamping device. In particular, the opening cross-section of the open area is larger than the opening cross-section of the opening channel of the cover element.

The spring-loaded clamping device may have an engagement area, in particular an opening in the optional housing of the spring-loaded clamping device, through which a tool can be inserted with which the clamping connection of the conductor clamped in the clamping device can be detached. This can be done by inserting an elongated tool by means of which a spring of the clamping device is tensioned by the user, causing the jaws to detach from each other, for example. In particular, if no housing is provided, the engagement area can also be realized by the clamping device not being covered.

The spring-loaded clamping device may also have an actuating device via which the clamping connection of the conductor clamped in the clamping device can be loosened without tools. The actuating device may include a movable pin, which may be movably mounted in particular in the housing or in the base body, the deflection of which allows for a spring of the clamping device to be clamped by the user, whereby the clamping jaws, for example, detach from each other.

Via a connection of the connecting section-especially designed in a non-destructive and reversible manner-with the complementary connecting section of the spring-loaded clamping device, the cover element is designed in particular to be removable for detaching the connecting strand. This connection, in particular, can be positive and can be a locking connection in particular. Alternatively or additionally, the cover element may have an actuating element that can be coupled with the spring-loaded clamping device in such a way that by activating the actuating element, the clamping connection can be detached, and the connecting strand can be removed from the opening channel. The actuating device may contain a movable pin, which can be movably mounted in particular in the cover element, through the deflection of which a spring of the clamping device can be clamped by the user, whereby the clamping jaws, for example, detach from each other.

A cup-shaped element can be provided in which the spring-loaded clamping device is arranged. The cup-shaped element can also be part of the spring-loaded clamping device. Such a cup-shaped element serves to spatially separate the spring-loaded clamping device, in particular the electrical contacts disposed therein, from the environment. In particular, a cup-shaped element serves as a potting cup, which makes it possible to apply a potting compound to a spring-loaded clamping device mounted on a printed circuit board, which covers the electrical contacts on the printed circuit board. The cup-shaped element prevents potting compound from penetrating the spring-loaded clamping device and thus prevents the reversibly clamped conductors from being glued by the potting compound.

When mounted on a printed circuit board, the cup-shaped element can be arranged particularly such that the opening of the cup-shaped element, through which the spring-loaded clamping device is inserted into the cup-shaped element, points away from the printed circuit board, i.e., points “upwards”. The cup-shaped element may have one, two or more openings or recesses through which contact pins or conductors of the spring-loaded clamping device may be routed, in particular in order to be connected to the circuit board. These openings are preferably placed in a bottom section of the cup-shaped element. A disadvantage of such openings, in which contact pins are routed outwards, is that when potting compound is used, this can penetrate through the openings into the inside of the cup and thus reach the clamped conductors.

The cup-shaped element can have a barrier device that is attached inside the cup-shaped element, in particular on its bottom plate. The barrier device prevents dust or potting compound from entering the bottom-side area of the contact pins. In particular, the barrier device may include a barrier layer which can be arranged and/or applied to the bottom plate of the cup-shaped element. This barrier layer can serve as a seal between the spring-loaded clamping device and the cup-shaped element.

For example, as an alternative or in addition to a barrier layer, the barrier device can have a material-locking paste that forms the barrier layer or strengthens the barrier effect.

The barrier device can also have barrier elements which, arranged between the spring-loaded clamping device and the cup-shaped element, provide a form-fitting connection or barrier between the spring-loaded clamping device and the cup-shaped element when the two components are connected. The barrier elements may be designed to create a form-fitting connection between the spring-loaded clamping device and the cup-shaped element and may in particular contain interlocking structures, in particular elevations and depressions. The barrier elements may, for example, form protrusions in the form of projections at the bottom of the potting cup with recesses in the form of grooves on the spring-loaded clamp in order to form a form-fitting connection.

The cup-shaped element may have a connecting section for connecting the cup-shaped element to the cover element. In this case, it is not necessary that the spring-loaded clamping device has this connecting section.

The barrier layer can be formed pf an electrically non-conductive material or contains it. The material can be elastomers in particular, in particular elastic and/or plastically prestressed elastomers, PU, silicones, as well as their foams (closed-pored) and/or gel-like characteristics. Also preferred for the material are solid curing potting compounds or adhesives on a 1- or 2 component basis, varnishes and pastes, pasty electrically non-conductive substrates or a combination of the above.

The invention also relates to a clamping system which has a spring-loaded clamping device and a cover element according to the invention that can be connected to it. A reversible connection of these two components of the clamping system offers the advantage that an engagement opening of the spring-loaded clamping device in the mounting position for the purpose of dust sealing is covered by the cover element and is therefore not accessible for loosening the clamping connection, but that by removing the cover element, access to the engagement opening and the release of the clamp is made possible again. The cover element may completely encapsulates the spring-loaded clamping device in the mounting position and has the opening channel as the sole opening in the mounting position.

The clamping system can have a single or multi-core connecting strand, which has an insulating jacket which can be arranged in a form-fitting and/or force-fit manner in the opening channel of the cover element. The cover element is then preferably completely sealed against the entry of particles into the interior of the cover element. Preferably, the cover element completely encapsulates the spring-loaded clamping device in the mounting position, in particular in that the opening channel is closed by the connecting strand.

The clamping system can also include a cup-shaped element, as described above. The spring-loaded clamping device can be arranged or formed in this. In particular, the cup-shaped element and the spring-loaded clamping device can also be firmly and/or integrally connected to each other.

A clamping system whose spring-loaded clamping device is firmly connected to the cover element according to the invention is also preferred, i.e., in which it is not intended to remove the cover element beforehand in order to release the contact or to remove the connected connecting strand. Such a clamping system offers the immediate functionality of a spring-loaded clamp, thus forming a spring-loaded clamp with the advantage of dust-tightness. The clamping system may then have an actuating element, in particular for loosening the clamping connection, which is arranged to be moved in the cover element, as already described. This tool-free detachability of the clamping connection avoids the need for an open engagement opening in the cover element and thus a potential gateway for dust ingress. In a preferred embodiment, the clamping system forms a spring-loaded clamp, which, compared to marketable spring-loaded clamps, offers the advantage of a dust-tight connection of the clamping device and the conductor and thus protection from the environment.

The invention also relates to a printed circuit board which is in particular equipped with at least one electronic component, and which has a cover element or a clamping system according to the invention.

The invention also relates to a method for manufacturing the cover element according to the invention, comprising the steps of: providing a material, in particular a non-electrically conductive plastic; and manufacturing the cover element as an integral component, in particular via an additive manufacturing process or by means of an injection molding process.

A connecting strand can be single-core or multi-core.

The invention also relates to a hand-held power tool, in particular an angle grinder, having a cover element according to the invention or having a clamping system according to the invention, or having a system according to the invention.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a perspective view, diagonally from the front, of a cover element according to the invention according to an example.

FIG. 2 shows a perspective view, diagonally from behind, of the cover element of FIG. 1.

FIG. 3 shows a perspective view, diagonally from the front, of a spring-loaded clamping device which is inserted into a potting cup and can be covered with the cover element of FIG. 1.

FIG. 4 shows a perspective view, diagonally from behind, of the spring-loaded clamping device shown in FIG. 3 which is inserted into the potting cup.

FIG. 5 shows a system formed of the cover element in FIG. 1 as well as the spring-loaded clamping device and the potting cup of FIG. 3 or 4 in a perspective exploded view, from diagonally front top.

FIG. 6 shows the system of FIG. 5 and a connecting strand that can be inserted into the cover element and into the spring-loaded clamping device in a perspective exploded view, from diagonally behind below.

FIG. 7 shows, in a perspective transparent side view, the cover element of FIG. 1.

FIG. 8 shows, in a perspective transparent side view, the spring-loaded clamping device of FIG. 3.

FIG. 9 shows, in a perspective transparent side view, the potting cup of FIG. 3.

FIG. 10 shows the components of FIGS. 7, 8 and 9 assembled in a clamping system in a perspective transparent side view.

FIG. 11 shows the components of FIG. 6 assembled in a clamping system in a perspective side view.

FIG. 12 shows a perspective view, diagonally from the front, of a circuit

board of a hand-held power tool equipped with two clamping systems of FIG. 11 and equipped with electronic components, without the connecting strands.

FIG. 13 shows a cross-sectional view of the cover element of FIG. 1.

FIG. 14 shows a detail of FIG. 13.

### DETAILED DESCRIPTION

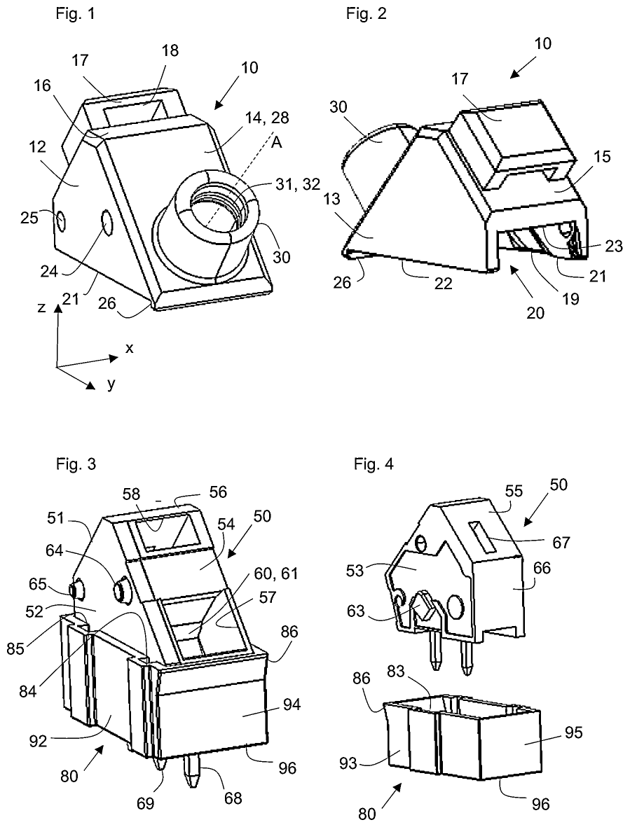

FIG. 1 shows a cover element 10 for covering a spring-loaded clamping device 50 that can be connected to a printed circuit board. The clamping device is used to connect a power cable to the corresponding mains voltage contact on a printed circuit board that has the electronic unit of a hand-held power tool, in particular an angle grinder.

The cover element 10 is present as a cover element 10 that has been integrally manufactured in the additive manufacturing process. This can be fitted to a spring-loaded clamping device 50 in order to encapsulate it in dusty environments with the connecting strand 100 inserted. The cover element 10 is designed as a cap element, i.e., as an enclosure that is fitted to the spring-loaded clamping device component 50. It has two opposing vertical side walls 12 and 13, as well as a diagonal front wall 14 and a diagonal back wall 15.

The front wall 14 forms a cover portion 28 for covering a conductor mount of the spring-loaded clamping device in the form of an open area which is to be protected from the ingress of metal dust.

An opening channel 30 extends vertically away from the front wall 14. In the area of the front wall 14, the opening channel has a first opening 33, which opens into the interior of the opening 20 of the cover element. The opening channel 30 is used for the form-and force-fit mounting of the connecting strand 100. On its inner side, the opening channel 30 has a ring-shaped protrusion 31, which runs concentrically around the central axis A of the opening channel 30. The protrusion forms the narrowest diameter 30 of the opening channel inwards. If a connecting strand 100 is inserted into the opening channel 30, the protrusion 31 serves to push in the flexible jacket 101 of the connecting strand 100 all around. This seals the opening of the opening channel 30 against the environment, in particular gas- and/or dust-tight. The protrusion 31 thus forms a seal 32. In addition, it fixes the connecting strand 100 against unwanted movements, e.g., vibrations that could impair the electrical contacting of the electrical contacts of the spring-loaded clamping device through the conductor 102 of the connecting strand 100.

The back wall 15 has a tab element 17, which includes a plate that is parallel to the back wall 15, which is integrally connected to the back wall via two base parts and forms an insertion channel 18 between the plate and the back wall. The tab element 17 can be used to dismantle the cover element by inserting a tool into the insertion channel 18 and gripping the cover element by means of the tool, loosening the connection between the cover element and the spring-loaded clamping device by force and thus removing the cover element.

The planar side walls 12, 13, the planar front wall 14 and the planar back wall 15 meet in an upper edge area 16 and thus close an interior of the cover element 10 upwards (in the positive z-direction). The choice, arrangement and shape of the walls depends on the nature of the spring-loaded clamping device 50, which is to be covered by the cover element 10, depending on the implementation.

The interior is open downwards (in the negative z-direction). This lower opening 20 is used to receive the upper part of the spring-loaded clamping device 50, which is received from below into the cover element 10 and is connected to it in a form-fitting manner.

As can be seen in FIG. 2, the back wall 15 is not completely extended down to the plane in which the lower edges 21, 22 of the side walls lie. Instead, the lower edge 23 of the back wall 15 ends above this level. This makes it easier to insert the spring-loaded clamping device 50 through the opening 20 into the interior of the cover element 10.

The placement of the cover element 10 on the spring-loaded clamping device is simplified by a guide device of the cover element 10. The guide device includes the guide groove 19, which extends linearly from the lower edge 21 of the inside of the side wall 12 in an oblique upward direction. The direction of the guide groove runs parallel to the virtual axis A, which forms the longitudinal axis of the hollow cylindrical opening channel 30.

When mounting the cover element 10 on the spring-loaded clamping device 50 up to the mounted position (mounting position), a connecting strand 100 already extends through the opening channel 30 of the cover element 10 in accordance with a preferred embodiment of the clamping system 200, wherein the conductor 102 is already clamped in the metallic clamping jaws of the spring-loaded clamping device. The clamping jaws are components of the clamping device located inside the spring-loaded clamping device. As the cover element 10 is not yet mounted when the conductor is inserted into the clamping jaws, a user can visually check the success of the contacting through the open area of the conductor mount, which allows for a view of the contacts.

To place the cover element 10 on the spring-loaded clamping device, the cover element 10 is then moved along the connecting strand 100, which is inserted into the open area of the spring-loaded clamping device 50 and the conductor of which ends in the clamping jaws. The open area is used to allow for the conductor to access the clamping device. If the cover element 10 is connected to the spring-loaded clamping device in the mounted position, the opening channel 30 of the cover element 10 is aligned to the open area 57 of the spring-loaded clamping device 50 in such a way that the connecting strand leads through the open area 57. The guide groove 19, which is aligned parallel to the opening channel 30 and the connecting strand 100 arranged therein, follows this direction of the axis A, which enables resistance-free and directional mounting of the cover element 10.

According to another preferred use of the clamping system 200, the cover element 10 is first attached to the spring-loaded clamping device up to the mounted position (mounting position). Only then is the connecting strand 100 inserted into the opening channel so that it is inserted into the conductor mount of the spring-loaded clamping device and the conductor 102 is pushed between the clamping jaws 61. As the cover element 10 is already installed when the conductor 102 is inserted into the clamping jaws 61, an experienced user cannot visually check the success of the contacting due to the covering by the cover element 10, but he can detect successful contact tactilely.

The front wall 14 of the cover element 10 has an extension 26 at its lower edge, which contains a hook-like projection pointing backwards (in the negative y-direction), which forms a connecting section 26. In the mounting position of the cover element on the spring-loaded clamping device, this counteracts a shift of the cover element relative to the spring-loaded clamping device to the back by means of a form-fitting attachment to a complementary edge 86 of the cup-shaped element 80.

FIG. 1 also shows the cylindrical openings 24 and 25 in the side wall 12 of the cover element 10. These openings 24, 25 each form a connecting section for the connection of the cover element 10 with pin-like protrusions 64, 65 of a complementary connecting section of the spring-loaded clamping device 50.

In the mounting position of the cover element 10 on the spring-loaded clamping device 50, with the connecting strand 100 inserted in the opening channel 30, there is no longer any opening between the interior of the cover element 10 and the environment through which dust could enter the interior. The lower edges 21, 22 are flush with the outer contour of the housing of the spring-loaded clamping device 50 and the upper edge 86 of the cup-shaped element 80, which can also be regarded as an optional component of the Spring-loaded clamping device 50. The openings 24 and 25 in the side wall 12 are closed by the complementary connecting pins 64, 65 of the spring-loaded clamping device and the opening channel 30 is tightly closed by the connecting strand 100.

FIG. 3 shows the spring-loaded clamping device 50, which is inserted into the potting cup 80, which serves as a cup-shaped element. The potting cup is used to protect the components arranged in it from contact with potting compound. In the embodiment, the spring-loaded clamping device 50 is a commercially available spring-loaded clamp and the cup-shaped element 80 is a matching potting cup in the embodiment. The cover element 10 was specially adapted in form and properties to these components and is particularly suitable in this case for retrofitting the components with a cover element 10 according to the invention.

The spring-loaded clamping device 50 has a housing 51, the shape of which is such that it is adapted to the inner contour of the cover element 10. Accordingly, it has parallel side walls 52 and 53 running vertically downwards, a sloping front wall 54 and a sloping back wall 55, wherein these walls merge in the upper edge 56, which in the mounting position is directly opposite the inside of the upper edge 16 of the cover element 10. Below the sloping back wall 55 of the housing 51 is the vertically downward back wall 66. Due to the vertical course, this back wall 66 and the side walls 52, 53 can be pushed into the cup-shaped element 80 from above. The cup-shaped element has the vertical side walls 92 and 93, as well as the vertical front wall 94 and the vertical back wall 95. These walls run up to bottom plate 96, to which they are integrally connected.

The sloping front wall 54 has the conductor mount 57, which is an open area 57 of the front wall. This is centered in the mounting position of the cover element 10 on the spring-loaded clamping device 50 on axis A, which is the longitudinal axis of the opening channel 30.

In particular, the two-part housing 51 has an engagement opening 58 on the sloping front wall 54, through which a user can intervene with a tool to open the spring of the clamping contacts, so that the conductor 102 can be removed. The sloping back wall 55 also has a latching opening 67. These openings 57, 67, 58 are covered by the cover element 10, which prevents metallic dust from entering the housing 51.

The spring-loaded clamping device 50 does not have to have a housing in principle, because the cover element 10 can form its housing. The clamping device 60 with the clamping jaws 61 and the contact pins 68 and 69 could also be arranged on a base part that could be covered by the cover element 10. Instead of an engagement opening for a tool engagement for the purpose of releasing the clamping device, the cover element 10 could, for example, have a movable and form-fitting actuating element arranged in an engagement opening of the cover element 10, by means of the manipulation of which a user could release the clamp.

Guide devices are provided for the insertion of the spring-loaded clamping device 50 into the cup-shaped element 80, which include the lower pin projections 74 and 75 on the side wall 52 of the housing 51 as guide elements. These guide elements are inserted from the vertical grooves 84 and 85 in the side wall 92 of the cup-shaped element 80.

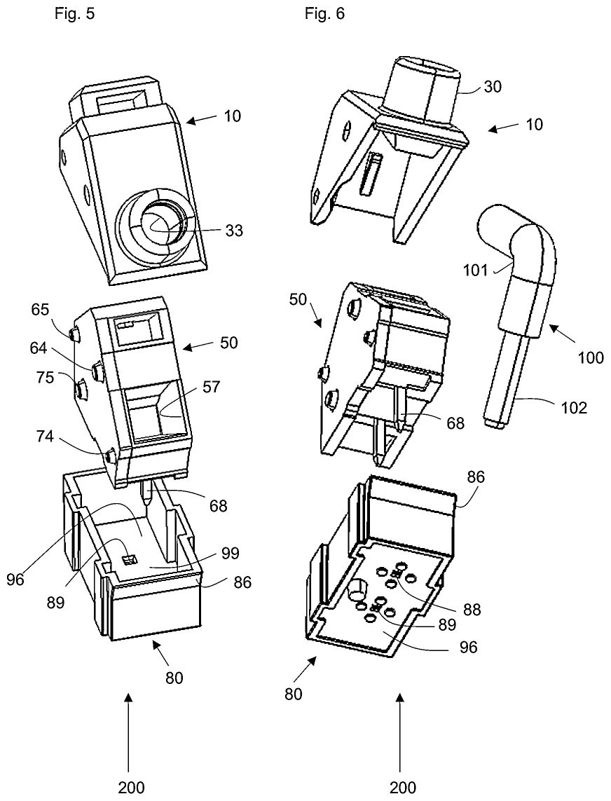

As can be seen in FIG. 4, the projection 63, which also serves as a guide element, is located on the side wall 53 and is guided in the vertically running groove 83 on the side wall 93 of the cup-shaped element 80. The guide elements ensure that when mounting the spring-loaded clamping device 50 in the cup-shaped element 80, the contact pins 68 and 69 of the spring-loaded clamping device 50 are inserted exactly into the assigned openings 88 and 89 of the bottom plate 96 (FIG. 6) of the cup-shaped element. This allows for the contact pins to protrude through the cup-shaped element 80 in the mounting position of the spring-loaded clamping device 50 in order to be connectable with corresponding contact points on the printed circuit board.

Inside the spring-loaded clamping device 50, the clamping device 60 is arranged in such a way that its clamping jaws 61 follow the conductor mount 57 in the direction inwards along the axis A. The clamping jaws 61 are metallically and electrically connected to the metallic contact pins 68 and 69.

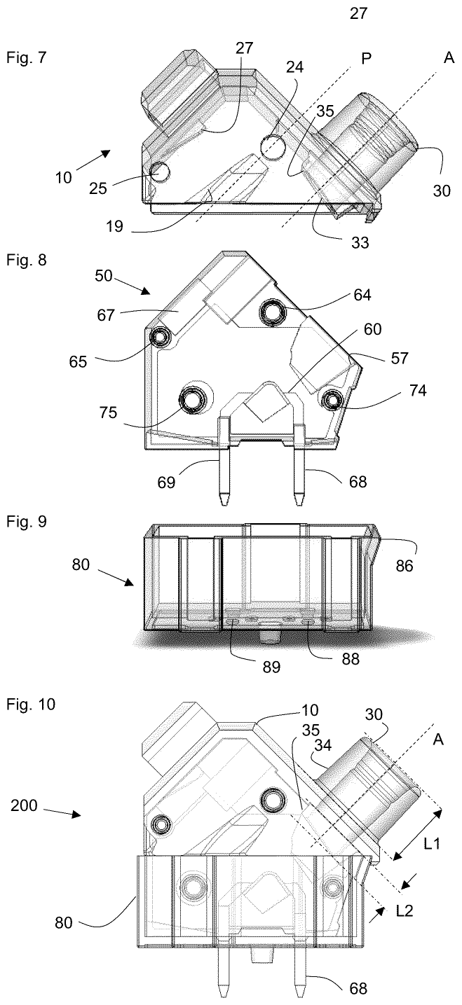

Also shown in FIG. 4 is the slit-shaped opening 67, which serves as a latching opening for the engagement of the locking cam 27, which is shown for example in FIG. 7.

FIG. 5 shows an exploded view of a clamping system 200, which includes the cover element 10, the spring-loaded clamping device 50 and the cup-shaped element 80. The view from above into the cup-shaped element 80 shows the top of the bottom plate 96 of the cup-shaped element, which is covered by a barrier layer 99. The barrier layer 99 is formed of an electrically non-conductive elastic material and is part of the bottom plate 96. The barrier layer prevents the ingress of dust in the direction of the contact pins 68, 69 and/or the ingress of potting compound through the bottom openings 88, 89 into the cup-shaped element 80 or into the spring-loaded clamping device 50. All components 10, 50 and 80 of the clamping system are made of electrically non-conductive material, e.g., thermoplastic.

The barrier layer against dust ingress towards the contact pins 68 and 69 can also be designed to be material-tight by ultrasonic welding of specially designed raised structures on the inner wall of the bottom plate 96 of the cup-shaped element 80 completely enclose the bottom openings 88 and 89 and connect them to the bottom side of the spring-loaded clamping device 50.

Together with the spring-loaded clamp 50 and the barrier layer 99, the potting cup 80 forms an electronic module assembled with THT (Through Hole Technology) and inserted directly into a printed circuit board and soldered.

FIG. 6 also shows the clamping system 200 of FIG. 5, from below, plus the connecting strand 100 to be inserted into the opening channel 30.

FIG. 7 shows a transparent side view of the cover element 10. Here, it can be seen in particular that the guide groove 19, in which the connecting pin 64 is guided, ultimately ends in the opening 24. When the cover element 10 is placed on the spring-loaded clamping device 50, the guide groove 19 of the cover element 10 slides along the connecting pin 64 until the connecting pin 64 enters the opening 24 in the mounting position and engages in it in a form-fitting manner. The path P of the guide groove 19 runs parallel to the axis A of the opening channel, as can clearly be seen here.

The inside of the front wall 14 of the cover element 10 has an inner section 35 of the opening channel 30, which extends from the inside of the front wall 14 inwards along the axis A. In the mounting position, the inner section 35 engages form-fittingly with the conductor mount 57 of the spring-loaded clamping device 50 and therefore forms a connecting section 35, which connects with the connecting section 57, which serves as a conductor mount. The inner section 35 has the first opening 33 of the opening channel, which is located in the mounting position within the conductor mount 57.

The locking cam 27 is formed on the inside of the back wall 15 of the cover element. In the mounting position in which the cover element 10 is mounted on the spring-loaded clamping device 50 and connected to it, the snap-in cam 27 is engaged in the locking opening 67 of the spring-loaded clamping device 50.

FIG. 8 shows the transparent side view of the spring-loaded clamping device 50, inside of which the clamping device 60 with contact pins 68, 69 can be seen in excerpts.

FIG. 9 shows the transparent side view of the cup-shaped element 80, in which the openings 88, 89 in the bottom plate are particularly recognizable.

FIG. 10 shows the transparent side view of the clamping system 200, which is encapsulated dust tight except for the opening of the opening channel 30. It is shown that the maximum length L1 of the outer section 34 of the opening channel 30, which faces outwards from the outside of the front wall 14, is several times greater than the length L2 of the inner section 35 of the opening channel 30. However, the outer section 34 could in principle also be shorter, in particular L2=L1 or L2>L1, preferably also L1=0 and/or L2=0. In particular, the opening channel could only extend through the thickness of a wall, in particular in this case the front wall 14, of the cover element.

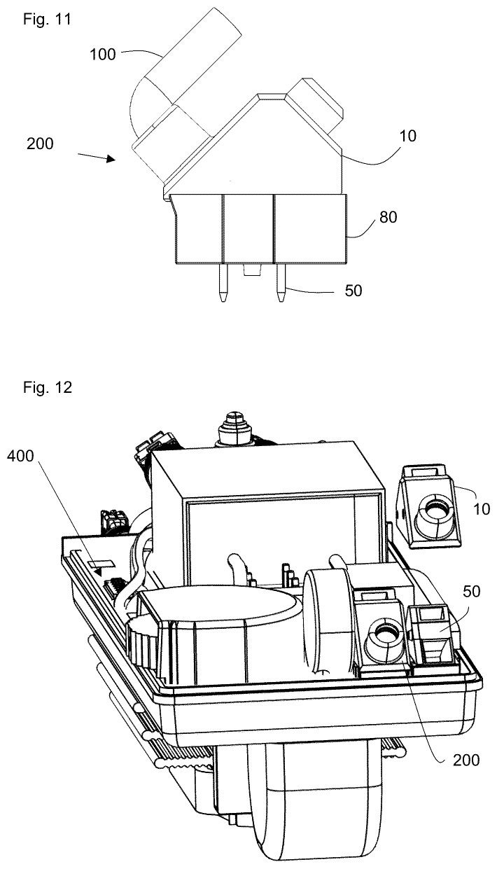

FIG. 11 shows the clamping system 200 in the connection configuration in which the connecting strand 100 is inserted into the opening channel and the conductor is clamped in the clamping device 60 and electrically contacted. After insertion of the connecting strand 100, the clamping system 200 is encapsulated dust tight.

FIG. 12 shows a perspective view of a printed circuit board 400, equipped with electronic components, of a hand-held power tool, in particular an angle grinder, on which two clamping systems 200 are attached and serve to connect the power cables.

The assembled circuit board has been encapsulated. The electronic encapsulation protects the

electronic components from contamination. To reduce the risk of potting compound entering, there are potting cups 80. These are intended to prevent the creep process of the potting material and to ensure that the spring-loaded clamp 50 does not fill up due to electronic potting and that its function is no longer guaranteed as a result. However, as it turns out, a potting cup 80 alone does not solve this problem. Therefore, according to the invention, a barrier layer 99, which prevents the potting compound from entering the cup 80, is provided on the bottom of the inside of the potting cup. In addition, the barrier layer ensures that it encloses the contact pins 68, 69 and thus that any metallic foreign objects that may enter cannot cause a short circuit. This agent can be a bonded paste that acts as a barrier layer. The barrier layer can alternatively also be formed of form-fitting elements, wherein, for example, projections in the form of protrusions at the bottom of the potting cup interact with recesses in the form of grooves on the spring-loaded clamp to form a material-tight connection.

The potting cup 80 here forms an interface to the cover element 10 according to the invention so that it can adequately seal the upper part of the spring-loaded clamp. The barrier layer 99 ensures that the part of the spring-loaded clamp 50 directed towards the bottom plate, and in particular the contacts 68, 69 of the spring-loaded clamp, which act as an interface to the printed circuit board, are passivated. The cover cap 10 receives the connecting strand 100 of the power cable in a force-fitting manner and, after the connection strand has been connected to the spring-loaded clamp, is placed on the spring-loaded clamp in a form-fitting manner, whereby the part of the spring-loaded terminal 50 reaching out of the electronics encapsulation at the top is shielded and terminates with the potting cup 80. There may be other elements on the cover cap 10 which facilitate the dismantling of the cover cap 10 and/or are used to lay the connecting strands 100 of the mains connection cable in the power tool.

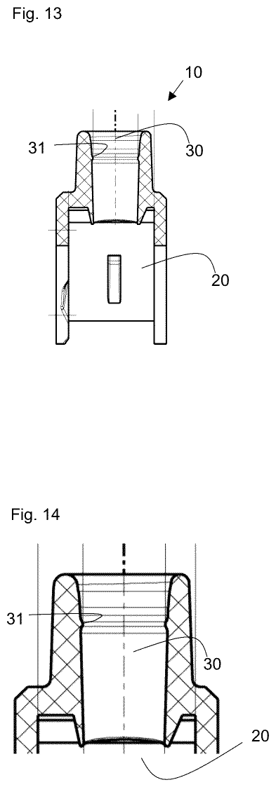

FIG. 13 shows a cross-section of the cover element 10 along the axis A of the opening channel 30 and perpendicular to the side walls 12 and 13.

The opening channel 30 can be seen, which has the annular protrusion 31 on its inside, which is the narrowest point in the opening channel and thus serves as an effective sealant. In addition, it can be seen that the opening channel 30 tapers in the direction of the interior 20 of the cover element. In other words, at the mouth 33 of the opening channel 30 into the interior 20, the diameter of the latter is smaller than at the opening channel entrance, into which a connecting strand is inserted from the outside into the cover element for connection with the spring-loaded clamping device.

FIG. 14 shows an enlarged detail of FIG. 13. The taper towards the interior 20 and the protrusion 31 are clearly visible.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A cover element to cover a spring-loaded clamping device connectable with a printed circuit board, the cover element comprising:
a connecting section to connect the cover element with a connecting section of the spring-loaded clamping device;
a cover portion to cover a conductor mount of the spring-loaded clamping device,
an opening channel formed in the cover portion, the opening channel provided for form-fitting and/or force-fit mounting of a connecting strand through which a conductor of the connecting strand is adapted to be guided and inserted into the conductor mount of the spring-loaded clamping device.

2. The cover element according to claim 1, wherein the opening channel is hollow and cylindrical and is designed for the form-fitting and/or force-fit mounting of a cylindrical connecting strand.

3. The cover element according to claim 1, wherein the opening channel has at least one seal to prevent a penetration of particles through the opening channel.

4. The cover element according to claim 3, wherein the seal has an annular protrusion on an inside of the opening channel.

5. The cover element according to claim 4, wherein this protrusion connects between the opening channel and the connecting strand to create a force-fit connection in that the protrusion is adapted to be pressed into a flexible material of an insulating jacket of the connecting strand.

6. The cover element according to claim 1, wherein the opening channel extends from the cover portion along a longitudinal axis and has a first opening into which a connecting strand is adapted to be inserted into the opening channel, and wherein the opening channel has a channel section which has a decreasing opening cross-section in the direction of the first opening and which ends in the first opening.

7. The cover element according to claim 1, wherein the opening channel is an opening cross-section, measured perpendicular to a longitudinal axis of the opening channel, with a diameter between 1 mm and 4 mm.

8. The cover element according to claim 1, wherein the cover element is an integral manufactured component or a component produced by an additive manufacturing process or injection molding.

9. The cover element according to claim 1, further comprising a guide groove via which the cover body is adapted to be slid onto a spring-loaded clamping device along a defined direction or parallel to a longitudinal axis of the opening channel.

10. A clamping system comprising:
the cover element according to claim 1; and
a spring-loaded clamping device having a conductor mount covered by the cover portion of the cover element.

11. The clamping system according to claim 10, wherein the cover element completely encapsulates the spring-loaded clamping device in a mounting position and has the opening channel as the sole opening.

12. The clamping system according to claim 10, further comprising a single or multi-core connecting strand comprising an insulating jacket that is arranged in a form-fitting and/or force-fit manner in the opening channel of the cover element.

13. A printed circuit board comprising at least one electronic component and the cover element according to claim 1 or a clamping system.

14. A hand-held power tool, in particular an angle grinder, comprising the cover element according to claim 1.

15. A method for manufacturing the cover element according to claim 1, the method comprising:
providing a material formed of a non-electrically conductive plastic; and
manufacturing the cover element as an integral component by an additive manufacturing process or by an injection molding process.
